(19) United States
(12) Patent Application Publication
(10) Pub. No.: US 2025/0374798 A1
(43) Pub. Date: Dec. 4, 2025

(54) DISPLAY DEVICE AND MANUFACTURING METHOD THEREOF

(71) Applicant: Samsung Display Co., LTD., Yongin-si (KR)

(72) Inventor: DOOHYUN LEE, Yongin-si (KR)

(21) Appl. No.: 19/019,014

(22) Filed: Jan. 13, 2025

(30) Foreign Application Priority Data
May 31, 2024 (KR) 10-2024-0071738

(51) Int. Cl. H10K 59/80; H10K 50/115; H10K 59/12; H10K 59/38; H10K 102/00

(52) U.S. Cl. CPC H10K 59/80522; H10K 50/115; H10K 59/1201; H10K 59/38; H10K 2102/331

(57) ABSTRACT

A display device includes a substrate, a plurality of pixels including a plurality of pixel circuit parts on the substrate, a plurality of first electrodes on the plurality of pixel circuit parts, a pixel insulating layer on the plurality of first electrodes, a second electrode on the pixel insulating layer and the plurality of first electrodes, a first pixel of the plurality of pixels including a first light emitting layer, and a second pixel of the plurality of pixels including a plurality of second light emitting layers, wherein the pixel insulating layer has a first pixel opening defining a light emitting region of the first pixel, and a second pixel opening defining a light emitting region of the second pixel, and wherein the pixel insulating layer has a boundary opening between the first light emitting region and the second light emitting region.

### CROSS-REFERENCE TO RELATED APPLICATION

The present application claims priority to and the benefit of Korean Patent Application No. 10-2024-0071738, filed on May 31, 2024, in the Korean Intellectual Property Office, the entire disclosure of which is incorporated herein by reference.

### BACKGROUND

### 1. Technical Field

Embodiments of the present disclosure relate to a display device and a method of manufacturing the display device.

### 2. Description of the Related Art

As display devices, light emitting display devices that provide an image by adjusting the brightness of light emitting diodes and liquid crystal display devices that display an image by adjusting the transmittance of a liquid crystal layer are widely used. Unlike liquid crystal displays, light emitting display devices do not require a separate light source such as a backlight, so the thickness and weight of the display device may be reduced. Additionally, light emitting display devices can exhibit high-quality characteristics such as low power consumption, high brightness, and high response speed.

A display device may include a display area corresponding to a screen that displays an image, and pixels may be arranged in the display area. Pixels may be implemented by light emitting diodes. A light emitting diode may include two electrodes and a light emitting layer arranged between them. One of the two electrodes may be a pixel electrode provided individually for each pixel, and the other may be a common electrode provided in common to a plurality of pixels.

The above information disclosed in this Background section is intended to enhance understanding of the background of the disclosure and may contain information that does not constitute prior art.

### SUMMARY

Aspects of one or more embodiments of the present disclosure are directed to improving the color purity and color reproducibility of the display device, improving the lifespan of the light emitting diode, and improving display quality by preventing or reducing leakage current between pixels.

Additional aspects will be set forth in part in the description which follows and, in part, will be apparent from the description, or may be learned by practice of the presented embodiments of the disclosure.

A display device according to one or more embodiments of the present disclosure includes a substrate, a plurality of pixels including a plurality of pixel circuit parts arranged on the substrate, a plurality of first electrodes arranged on a plurality of pixel circuit parts, a pixel insulating layer arranged on the plurality of first electrodes, a second electrode arranged on the pixel insulating layer and the plurality of first electrodes, a first pixel of the plurality of pixels includes a first light emitting layer arranged between a first electrode of the plurality of first electrodes and the second electrode; and a second pixel of the plurality of pixels includes a plurality of second light emitting layers arranged between another first electrode of the plurality of first electrodes and the second electrode, wherein the pixel insulating layer has a first pixel opening above the first electrode of the first pixel, and a second pixel opening above the another first electrode of the second pixel, wherein the first pixel opening defines a light emitting region of the first pixel, and the second pixel opening defines a light emitting region of the second pixel, and wherein the pixel insulating layer has a boundary opening arranged between the light emitting region of the first pixel and the light emitting region of the second pixel.

In one of more embodiments, in a plan view, the boundary opening may be formed in the form of a closed curve along the periphery of the light emitting region of the second pixel.

In one of more embodiments, the pixel insulating layer may further have a first opening arranged between the light emitting region of the second pixel and the boundary opening, and the first opening may be arranged in an area surrounded by the boundary opening.

In one of more embodiments, a first voltage transfer electrode arranged on the substrate, and a second voltage transfer electrode arranged above the plurality of pixel circuits and electrically connected to the first voltage transfer electrode may be further included, and the second electrode of the second pixel may be electrically connected to the second voltage transfer electrode through the first opening.

In one of more embodiments, the display device may further include a first common layer arranged on the first electrode of the first pixel and the pixel insulating layer, and the first common layer may have a first common layer opening that overlaps the first opening in the plan view.

In one of more embodiments, the display device may further include a first common layer arranged on the first electrode of the first pixel and the pixel insulating layer, and the first common layer may have a second common layer opening that overlaps the boundary opening in a plan view.

In one of more embodiments, the side surface of the second common layer opening may be connected to the side surface of the boundary opening and may be parallel to form one flat side surface.

In one of more embodiments, the display device may further include a blocking part arranged above the plurality of pixel circuit parts, and the boundary opening may be arranged above the blocking part.

In one of more embodiments, the second electrode at the second pixel may be separated from the second electrode at the first pixel by a step of the boundary opening.

In one of more embodiments, the second electrode may be arranged within the boundary opening and may include a portion arranged above the blocking part.

In one of more embodiments, the display device further includes a first common layer arranged over the first electrode of the first pixel and the pixel insulating layer, wherein the first common layer may have a third common layer opening that overlaps the second pixel opening in a plan view.

In one of more embodiments, the side surface of the third common layer opening may be connected to the side surface of the second pixel opening and may be parallel to form one flat side surface.

In one of more embodiments, an acute angle defined by at least a portion of the side surface of the second pixel opening and a first direction normal (e.g., perpendicular) to a top surface of the substrate may be smaller than an acute angle defined by the side surface of the first pixel opening and the first direction.

In one of more embodiments, the first light emitting layer may include quantum dots, and the plurality of second light emitting layers may include an organic light emitting material.

In one of more embodiments, the display device may further include a plurality of second common layers alternately stacked with the plurality of second light emitting layers.

In one of more embodiments, the first pixel may be to emit red or green light, and the second pixel may be to emit blue light.

In one of more embodiments, the display device further includes an encapsulation portion arranged on the second electrode, and at least one of a color filter layer and/or a color conversion layer arranged on the encapsulation portion, and the color conversion layer may include quantum dots.

A method of manufacturing the display device according to one or more embodiments of the present disclosure includes forming a plurality of pixel circuit parts of a plurality of pixels on a substrate, forming a plurality of first electrodes and a blocking part on the plurality of pixel circuit parts, the plurality of first electrodes and forming a pixel insulating layer on the blocking part, patterning the pixel insulating layer to form a first pixel opening of a first pixel of the plurality of pixels, the first pixel opening defining a light emitting region of the first pixel, and forming a first light emitting layer in the first pixel opening, patterning the pixel insulating layer to form a boundary opening arranged above the blocking part and a second pixel opening of a second pixel of the plurality of pixels, the second pixel opening defining a light emitting region of the second pixel, forming a plurality of second light emitting layers within the second pixel opening, and forming a second electrode on the first light emitting layer and the second light emitting layer, wherein the boundary opening may be arranged between the light emitting region of the first pixel and the light emitting region of the second pixel.

In one of more embodiments, the step (e.g., act or task) of the patterning the pixel insulating layer to form the boundary opening and the second pixel opening may include laser cutting the pixel insulating layer to form the boundary opening and the second pixel opening.

In one of more embodiments, the method may further include forming a first common layer over a first electrode of the plurality of first electrodes and the pixel insulating layer at the first pixel before the step (e.g., act or task) of patterning the pixel insulating layer to form the boundary opening and the second pixel opening, and forming a plurality of second common layers over another first electrode of the plurality of first electrodes at the second pixel after the step (e.g., act or task) of patterning the pixel insulating layer to form the boundary opening and the second pixel opening, wherein, in the step (e.g., act or task) of patterning the pixel insulating layer to form the boundary opening and the second pixel opening, the first common layer may be patterned to form a common layer opening corresponding to each of the boundary opening and the second pixel opening.

According to one or more embodiments of the present disclosure, an electronic device includes a display device including: a substrate; a plurality of pixels including a plurality of pixel circuit parts on the substrate; a plurality of first electrodes on the plurality of pixel circuit parts; a pixel insulating layer on the plurality of first electrodes; a second electrode on the pixel insulating layer and the plurality of first electrodes; a first pixel of the plurality of pixels including a first light emitting layer between a first electrode of the plurality of first electrodes and the second electrode; and a second pixel of the plurality of pixels including a plurality of second light emitting layers between another first electrode of the plurality of first electrodes and the second electrode, wherein the pixel insulating layer has a first pixel opening above the first electrode of the first pixel, and a second pixel opening above the another first electrode of the second pixel, wherein the first pixel opening defines a light emitting region of the first pixel, and the second pixel opening defines a light emitting region of the second pixel, and wherein the pixel insulating layer has a boundary opening between the light emitting region of the first pixel and the light emitting region of the second pixel.

In one or more embodiments, the electronic device may include a mobile phone, a smartphone, a tablet personal computer, a mobile communication terminal, an electronic notebook, an e-book, a portable multimedia player, a navigation system, an ultramobile personal computer, a television, a laptop, a monitor, a billboard, a smart watch, a watch phone, a glasses-type display, a head mounted display, or a car display.

According to one or more embodiments, the color purity and color reproducibility of the display device may be improved, the lifespan of the light emitting diode may be improved, and display quality may be improved by preventing or reducing leakage current between pixels.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view of a display device according to one or more embodiments of the present disclosure;

FIG. 2 is a diagram showing the arrangement of a plurality of pixels of a display device, according to one or more embodiments of the present disclosure;

FIG. 3 is a diagram showing the arrangement of a plurality of pixels included in one pixel group of a display device, according to one or more embodiments of the present disclosure;

FIG. 4 is a cross-sectional view of the display device of FIG. 3 taken along the line A1-A2, according to one or more embodiments of the present disclosure;

FIG. 5 is a cross-sectional view of a light emitting element included in one pixel of a display device according to one or more embodiments of the present disclosure;

FIG. 6 is a pixel circuit diagram of one pixel of a display device according to one or more embodiments of the present disclosure;

FIG. 7 is a cross-sectional view of the display device of FIG. 3 taken along the line A1-A2, according to one or more embodiments of the present disclosure;

FIG. 8 is a cross-sectional view of the display device of FIG. 3 taken along the line A1-A2, according to one or more embodiments of the present disclosure;

FIG. 9 is a cross-sectional view of the display device of FIG. 3, taken along the line A1-A2, at a stage of a manufacturing process of a method of manufacturing a display device, according to one or more embodiments of the present disclosure;

FIG. 10 is a cross-sectional view of the display device of FIG. 3, taken along the line A1-A2, at the next stage of the manufacturing process shown in FIG. 9, according to one or more embodiments of the present disclosure;

FIG. 11 is a cross-sectional view of the display device of FIG. 3, taken along the line A1-A2, at the next stage of the manufacturing process shown in FIG. 10, according to one or more embodiments of the present disclosure;

FIG. 12 is a cross-sectional view of the display device of FIG. 3, taken along the line A1-A2, at the next stage of the manufacturing process shown in FIG. 11, according to one or more embodiments of the present disclosure;

FIG. 13 is a cross-sectional view of the display device of FIG. 3, taken along the line A1-A2, at the next stage of the manufacturing process shown in FIG. 12, according to one or more embodiments of the present disclosure;

FIG. 14 is a cross-sectional view of the display device of FIG. 3, taken along the line A1-A2, at the next stage of the manufacturing process shown in FIG. 13, according to one or more embodiments of the present disclosure;

FIG. 15 is a cross-sectional view of the display device of FIG. 3, taken along the line A1-A2, at the next stage of the manufacturing process shown in FIG. 14, according to one or more embodiments of the present disclosure; and

FIG. 16 is a cross-sectional view of the display device of FIG. 3, taken along the line A1-A2, at the next stage of the manufacturing process shown in FIG. 15, according to one or more embodiments of the present disclosure.

FIG. 17 is a block diagram of an electronic device according to an embodiment.

FIG. 18 to FIG. 20 are schematic diagrams of electronic devices according to various embodiments.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals denote like elements throughout the attached drawings and the written description, and thus, duplicative descriptions thereof may not be provided.

In addition, the size and thickness of each component shown in the drawings may be arbitrarily shown for convenience of explanation, so the present disclosure is not necessarily limited to that which is shown. In the drawings, the thicknesses may be enlarged to clearly express various layers and areas. And in the drawings, for convenience of explanation, the thicknesses of some layers and regions may be exaggerated. In the drawings, the relative sizes of elements, layers, and regions may be exaggerated for clarity.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof.

In the context of the present disclosure and unless otherwise defined, a plan view is an orthographic projection of a three-dimensional object from the position of a horizontal plane through the object. That is, it is a top-down view, showing the layout and spatial relationships of various elements within the object or structure. A plan view based on the direction DR3 refers to a top-down view of the display panel, as if looking directly down onto the surface from above. In this context, DR3 is the direction perpendicular or normal to the plane defined by the first direction (DR1) and the second direction (DR2). This refers to that in a plan view, the arrangement of sub-pixels, pads, and other components as they are laid out on the substrate can be seen, without any perspective distortion. When reference is made to “in a cross-section,” this refers to when a cross-section of the target portion is cut vertically and viewed from the side.

As used herein, the terms “use,” “using,” and “used” may be considered synonymous with the terms “utilize,” “utilizing,” and “utilized,” respectively.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the singular forms “a,” “an” and “the” are intended to include the plural forms as well, unless the context clearly indicates otherwise.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

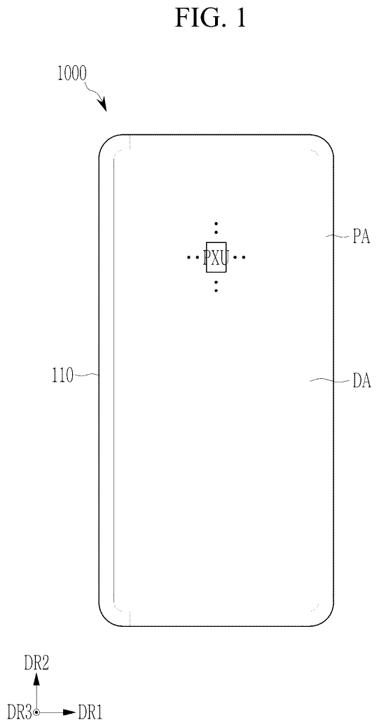

A display device according to one or more embodiments will be described with reference to FIGS. 1, 2, and 3.

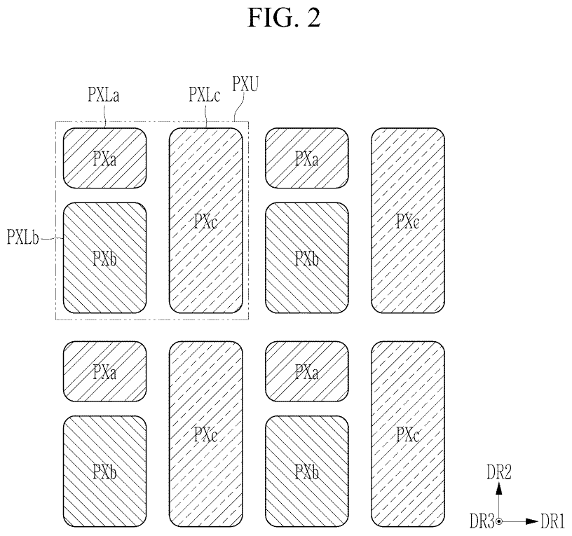

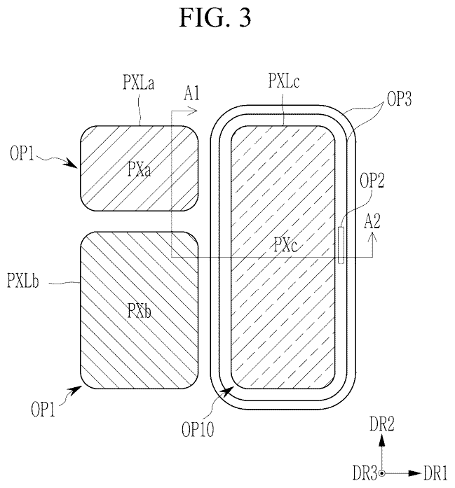

FIG. 1 is a plan view of a display device according to one or more embodiments of the present disclosure, FIG. 2 is a diagram showing the arrangement of a plurality of pixels of the display device according to one or more embodiments of the present disclosure, and FIG. 3 is a diagram showing the arrangement of a plurality of pixels included in a pixel group of the display device according to one or more embodiments of the present disclosure.

The display device 1000 according to one or more embodiments is a device for displaying videos and/or still images, and may be used not only in portable electronic devices, such as mobile phones, smartphones, tablet personal computers (tablet PCs), mobile communication terminals, electronic notebooks, e-books, portable multimedia players (PMPs), navigation systems, and/or ultramobile PCs (UMPCs), but may also be used as display screens for one or more suitable products such as televisions, laptops, monitors, billboards, and/or the Internet of Things IoT. Additionally, the display device 1000 according to one or more embodiments may be used in wearable devices such as smart watches, watch phones, glasses-type (kind) displays, and/or head mounted displays (HMDs). Additionally, the display device 1000 according to one or more embodiments may be used as a car display, such as a display in the dashboard of a car, the center information display (CID) arranged on the car's center fascia or dashboard, a room mirror display that replaces the car's side mirrors, and/or a display placed on the back of the front seats for entertainment in the rear seats of the car.

Referring to FIG. 1, the display device 1000 according to one or more embodiments may include a display panel including a display area DA capable of displaying an image and a peripheral area PA around the display area DA. The display panel may include a substrate 110. The display area DA includes a plurality of pixel groups PXU, which are units for displaying an image, and the peripheral area PA may or may not display an image. The peripheral area PA may be around (e.g., surround) the display area DA, but the present disclosure is not limited thereto.

The display area DA may have a display surface parallel to the first direction DR1 and the second direction DR2. The normal (perpendicular) direction of the display surface on which an image is displayed—that is, the thickness direction of the display panel—may be parallel to a third direction DR3.

The display panel may be a rigid display panel, but the present disclosure is not limited thereto, and the display panel may be a flexible display panel. The display panel may be a light emitting display panel including a plurality of light emitting diodes.

Referring to FIG. 2, a pixel group PXU of a display device according to one or more embodiments may include a plurality of pixels PXa, PXb, PXc that may be to emit light of different colors. The plurality of pixels PXa, PXb, PXc may include a first pixel PXa capable of emitting light of a first color, a second pixel PXb capable of emitting light of a second color, and a third pixel PXc capable of emitting light of a third color. For example, the first color may be red, the second color may be green, and the third color may be blue.

Each pixel PXa, PXb, PXc may include a pixel circuit part including at least one transistor and a light emitting element connected thereto. Each pixel PXa, PXb, PXc may include a pixel circuit part, a light emitting element, and a corresponding light emitting region.

Each pixel PXa, PXb, PXc may have a light emitting region PXLa, PXLb, PXLc, which is an area that may be to emit light. Referring to FIG. 2, the light emitting regions PXLa, PXLb, PXLc of the plurality of pixels PXa, PXb, PXc may be arranged with regularity in a plan view. For example, the light emitting region PXLa of the first pixel PXa and the light emitting region PXLb of the second pixel PXb may be alternately arranged in the second direction DR2, and the light emitting region PXLc may be alternately arranged in the first direction DR1 with the light emitting region PXLa of the first pixel PXa and/or the light emitting region PXLb of the second pixel PXb. The planar areas of at least two of the light emitting region PXLa of the first pixel PXa, the light emitting region PXLb of the second pixel PXb, and/or the light emitting region PXLc of the third pixel PXc may be different from each other.

A plurality of pixel groups PXU may also be arranged with regularity in a plan view. For example, a plurality of pixel groups PXU may be arranged roughly in a matrix form, but the arrangement is not limited thereto.

Referring to FIG. 3, each light emitting region PXLa, PXLb, PXLc of the plurality of pixels PXa, PXb, PXc may be defined by pixel openings OP1, OP10 of the pixel insulating layer, which will be described in more detail later. For example, the light emitting regions PXLa, PXLb of the first pixel PXa and the second pixel PXb may be defined by the pixel opening OP1 of the pixel insulating layer, and the light emitting region PXLc of the third pixel PXc may be defined by the pixel opening OP10 of the pixel insulating layer. While the following description may refer to pixels PXa, PXb and PXc (and their respective or associated components) in the singular, the description may apply to each of the pixels PXa, PXb and PXc (and their respective or associated components) in the display panel.

A boundary opening OP3 of the pixel insulating layer may be arranged around the light emitting region PXLc of the third pixel PXc among the plurality of pixels PXa, PXb, PXc. In a plan view, the boundary opening OP3 may be continuously formed in a closed curve shape around the light emitting region PXLc of the third pixel PXc. The boundary opening OP3 may be arranged between the light emitting region PXLa of the first pixel PXa and/or the light emitting region PXLb the second pixel PXb, and the light emitting region PXLc of the third pixel PXc. In other words, the boundary opening OP3 may be arranged between the light emitting region PXLa of the first pixel PXa and the light emitting region PXLc of the third pixel PXc or between the light emitting region PXLb the second pixel PXb and the light emitting region PXLc of the third pixel PXc. The third pixel PXc may be electrically separated from the first pixel PXa and the second pixel PXb by the boundary opening OP3. This will be described in more detail later with reference to the cross-sectional structure.

The pixel insulating layer may further include an opening OP2. The opening OP2 may be arranged between the light emitting region PXLc and the border opening OP3 of the third pixel PXc, and may be spaced and/or apart (e.g., spaced apart or separated) from the light emitting region PXLc and the border opening OP3 in a plan view. The opening OP2 may be arranged within an area surrounded by the boundary opening OP3 (or an area in which the boundary opening OP3 is around the opening OP2). FIG. 3 shows that the opening OP2 is arranged around the periphery of the light emitting region PXLc of the third pixel PXc, but depending on the embodiment, the opening OP2 may be arranged at the periphery of the light emitting region PXLa of the first pixel PXa or the light emitting region PXLb of the second pixel PXb.

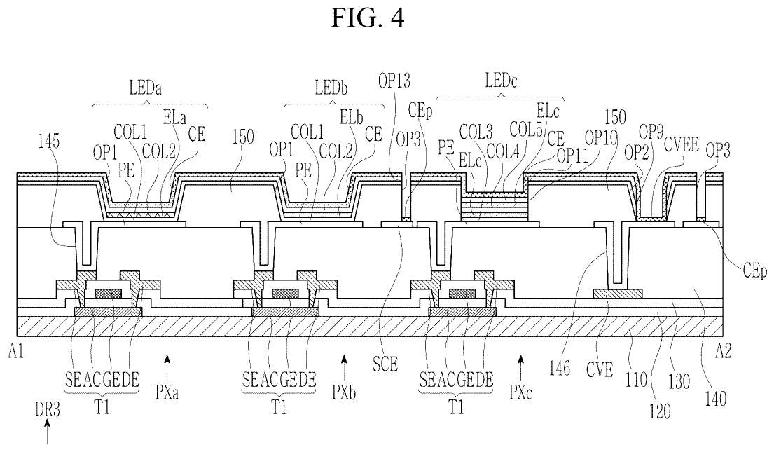

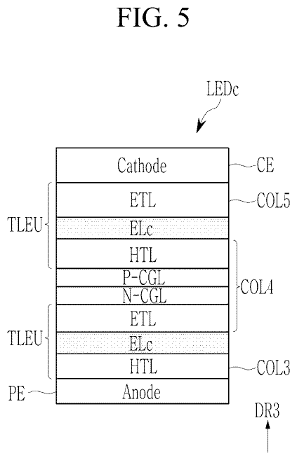

A cross-sectional structure of a display device according to one or more embodiments will be described with reference to FIGS. 4 and 5 along with FIGS. 1 to 3 described above.

FIG. 4 is a cross-sectional view of the display device of FIG. 3 taken along the line A1-A2, according to one or more embodiments of the present disclosure, and FIG. 5 is a cross-sectional view of a light emitting element included in one pixel of the display device according to one or more embodiments of the present disclosure.

Referring to FIG. 4, a display device according to one or more embodiments may include a substrate 110. The substrate 110 may include a plastic material such as polyimide or glass. The substrate 110 may include a flexible material that may be bent or folded, and may be a single layer or a multilayer.

In one or more embodiments, a buffer layer containing an inorganic insulating material or an organic insulating material may be further arranged on the substrate 110.

A semiconductor layer AC may be arranged on the substrate 110. The semiconductor layer AC may include a conductive region and a channel region. For example, the semiconductor layer AC may include a plurality of active regions, each of which include two conductive regions and a channel region, where the conductive regions are on opposite sides of the channel region. The semiconductor layer AC may include a semiconductor material such as amorphous silicon, polycrystalline silicon, and/or oxide semiconductor.

A first insulating layer 120 may be arranged on the semiconductor layer AC. The first insulating layer 120 may have a single-layer or multilayer structure and may include an inorganic insulating material. The first insulating layer 120 may be a gate insulating layer.

A gate electrode GE (e.g., a plurality of gate electrodes GE) may be arranged on the first insulating layer 120. The gate electrode GE may overlap the channel region of the semiconductor layer AC. For example, each gate electrode GE may overlap a channel region of one of the active regions of the semiconductor layer AC. The gate electrode GE may have a single-layer or multilayer structure and may include a metal material such as molybdenum (Mo), aluminum (Al), copper (Cu), titanium (Ti), and/or an alloy of at least two of these.

A second insulating layer 130 may be arranged on the gate electrode GE. The second insulating layer 130 may have a single-layer or multilayer structure and may include an inorganic insulating material or an organic insulating material.

A first conductive layer including a source electrode SE (e.g., a plurality of source electrodes SE), a drain electrode DE (e.g., a plurality of drain electrodes DE), and a first voltage transfer electrode CVE (e.g., a plurality of voltage transfer electrodes CVE) may be arranged on the second insulating layer 130. The first conductive layer may have a single-layer or multilayer structure, and may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and/or alloys of at least two of these.

The source electrode SE and the drain electrode DE may be electrically connected to each conductive region of the semiconductor layer AC through contact holes in the second insulating layer 130 and the first insulating layer 120. For example, for each active region of the semiconductive layer AC, a source electrode SE of the plurality of source electrodes may be electrically connected to one of the two conductive regions and a drain electrode DE of the plurality of drain electrodes may be electrically connected to the other of the two conductive regions that is on the opposite side of the channel region to the first conductive region.

The semiconductor layer AC, gate electrode GE, source electrode SE, and drain electrode DE may constitute the first transistor T1. The first transistor T1 may be included in the pixel circuit part of each pixel PXa, PXb, PXc (e.g., each pixel may include a first transistor T1).

The first voltage transfer electrode CVE may be electrically separated from the source electrode SE and the drain electrode DE constituting the first transistor T1, and may be to transmit a common voltage. The first voltage transfer electrode CVE may receive the common voltage through the pad portion of the peripheral area PA on the substrate 110.

A third insulating layer 140 may be arranged on the first conductive layer including the source electrode SE, the drain electrode DE, and the first voltage transfer electrode CVE. The third insulating layer 140 may include organic insulating materials such as one or more suitable polymer resins. The third insulating layer 140 may flatten the top surface of the first transistor T1. The third insulating layer 140 may have a flatter top surface than the first insulating layer 120 and the second insulating layer 130.

A pixel electrode layer including a first electrode PE (e.g., a plurality of first electrodes PE, for example, one per pixel), a second voltage transfer electrode CVEE (e.g., a plurality of second voltage transfer electrodes CVEE), and a blocking part SCE (e.g., a plurality of blocking parts) may be arranged on the third insulating layer 140. The pixel electrode layer may have a single-layer or multilayer structure and may include at least one of a transparent conductive oxide film such as IZO, IGZO, and ITZO, or a metal.

The first electrode PE may be an anode electrode or a pixel electrode. The first electrode PE may be arranged in each pixel PXa, PXb, PXc, and the first electrodes PE of neighboring pixels PXa, PXb, PXc may be separated and insulated from each other. The first electrode PE may be electrically connected to the source electrode SE of the first transistor T1 through a contact hole 145 of the third insulating layer 140. The first electrode PE may receive a data voltage from the source electrode SE. Depending on the embodiment, the first electrode PE may be electrically connected to the drain electrode DE of the first transistor T1 to receive a data voltage. The second voltage transfer electrode CVEE is electrically connected to the first voltage transfer electrode CVE through the contact hole 146 of the third insulating layer 140 and may receive a common voltage.

As shown in FIG. 4, the blocking part SCE may be spaced and/or apart (e.g., spaced apart) and/or separated from the adjacent first electrode PE or second voltage transfer electrode CVEE, and may be physically and electrically connected to at least some of them. The blocking part SCE may prevent or reduce the likelihood of the layers below the blocking part SCE from being damaged in the laser cutting process, which will be described in more detail later. In a plan view, the blocking part SCE may be continuously formed in a closed curve shape along part or all of the surrounding area of the light emitting region PXLc of the third pixel PXc.

A pixel insulating layer 150 may be arranged on the pixel electrode layer and the third insulating layer 140. The pixel insulating layer 150 is also called a pixel defining layer PDL. The pixel insulating layer 150 may include an organic insulating material such as polyimide, polyamide, acrylic resin, benzocyclobutene, or phenol resin. Depending on the embodiment, the pixel insulating layer 150 may further include a black pigment.

The pixel insulating layer 150 includes a pixel opening OP1 that overlaps the first electrode PE of the first pixel PXa and a pixel opening OP1 that overlaps the second pixel PXb, and may include a pixel opening OP10 that overlaps the first electrode PE of the third pixel PXc.

The pixel insulating layer 150 may further include an opening OP2 arranged above the second voltage transfer electrode CVEE, and a boundary opening OP3 arranged above the blocking part SCE. The width of the boundary opening OP3 may be smaller than the width of the pixel openings OP1, OP10. Additionally, the width of the boundary opening OP3 may be smaller than the width of the opening OP2. Here, the width may be a direction normal (e.g., perpendicular) to the third direction DR3—that is, a width in a plan view.

In the cross-sectional view, the acute angle formed by the side of the pixel insulating layer 150 that forms the boundary opening OP3 and the pixel opening OP10 with the third direction DR3 may be smaller than the acute angle formed by the side of the pixel insulating layer 150 that forms the pixel opening OP1 with the third direction DR3. For example, in the cross-sectional view, the sides of the pixel insulating layer 150 forming the boundary opening OP3 and the pixel opening OP10 may stand more normal (e.g., perpendicular) to the upper surface of the substrate 110 than the sides of the pixel insulating layer 150 forming the pixel opening OP1. In this case, the boundary opening OP3 and the pixel opening OP10 may be formed through a laser cutting process to be described in more detail later.

According to one or more embodiments, at least part of the side of the pixel insulating layer 150 that forms the pixel opening OP10 of the third pixel PXc may have a shape or an angle relative to the third direction DR3 that is substantially identical or similar to that of the side of the pixel insulating layer 150 that forms the pixel opening OP1 of the first pixel PXa or the pixel opening OP1 of the second pixel PXb. In such embodiments, a portion of the pixel opening OP10 may be formed by a laser cutting process, which will be described in more detail later, or may not be removed in the laser cutting process.

At least a portion of the side surface of the pixel insulating layer 150 forming the opening OP2 may be substantially the same or similar to the side surface and shape of the pixel insulating layer 150 forming the pixel opening OP1 of the first pixel PXa or the pixel opening OP1 of the second pixel PXb, or the angle formed with respect to the third direction DR3 may be the same or similar to each other.

According to one or more embodiments, at least part of the side of the pixel insulating layer 150 forming the opening OP2 may form an acute angle with the third direction DR3 that is smaller than the acute angle formed by the side of the pixel insulating layer 150 forming the pixel opening OP1 with the third direction DR3. For example, in the cross-sectional view, the side of the pixel insulating layer 150 forming the opening OP2 may stand more normal (e.g., perpendicular) to the upper surface of the substrate 110 than the side of the pixel insulating layer 150 forming the pixel opening OP1. In such embodiments, at least a portion of the opening OP2 may be formed through a laser cutting process to be described in more detail later.

In one or more embodiments, at least one of the layered structure and composition of the light emitting layer and/or the common layer, which are arranged above the first electrode PE of the first pixel PXa or the first electrode PE of the second pixel PXb and within the pixel opening OP1, may be different from at least one of the layered structure and the composition of the light emitting layer and/or the common layer, respectively, which are arranged above the first electrode PE of the third pixel PXc and within the pixel opening OP10.

For example, on top of the first electrode PE of the first pixel PXa, there may be a first light emitting layer ELa and common layers COL1, COL2, and on top of the first electrode PE of the second pixel PXb, there may be a second light emitting layer ELb and common layers COL1, COL2. A plurality of third light emitting layers ELc and a plurality of common layers COL3, COL4, and COL5 may be arranged on the first electrode PE of the third pixel PXc.

Regarding the first pixel PXa and the second pixel PXb, each of the first and second light emitting layers ELa and ELb may be arranged within the pixel opening OP1 of the pixel insulating layer 150.

The first light emitting layer ELa and the second light emitting layer ELb according to one or more embodiments may include (e.g., a plurality of) quantum dots. Quantum dots (hereinafter also referred to as semiconductor nanocrystals) may include group II-VI compounds, group III-V compounds, group IV-VI compounds, group IV elements or compounds, group I-III-VI compounds, group II-III-VI compounds, group I-II-IV-VI compounds, and/or a (e.g., any suitable) combination thereof. Quantum dots may not contain cadmium. Depending on the embodiment, the quantum dot may have a core-shell structure including a core including the nanocrystal and a shell around (e.g., surrounding) the core. The shell of the quantum dot may serve as a protective layer to maintain semiconductor properties by preventing or reducing chemical denaturation of the core and/or as a charging layer to impart electrophoretic properties to the quantum dot. The shell may be a single layer or multilayer. The interface between the core and the shell may have a concentration gradient in which the concentration of elements that are present in the shell decreases toward the center. Examples of the shell of quantum dots include metal or non-metal oxides, semiconductor compounds, and/or a (e.g., any suitable) combination thereof.

The composition and/or size of the quantum dots included in the first light emitting layer ELa may be different from the composition and/or size of the quantum dots included in the second light emitting layer ELb. Quantum dots included in the first light emitting layer ELa of the first pixel PXa may be to emit first color light, which may be red, and the maximum emission peak wavelength of these quantum dots may be 600 nm or more—for example, 610 nm or more, 615 nm or more, or 620 nm or less, and 650 nm or less, 645 nm or less, 640 nm or less, 635 nm or less, or 630 nm or less. Quantum dots included in the second light emitting layer ELb of the second pixel PXb may be to emit second color light, which may be green, and the maximum emission peak wavelength of these quantum dots may be 490 nm or more—for example, 500 nm or more, 510 nm or more, 520 nm or more, 530 nm or more and 560 nm or less, 550 nm or less, 545 nm or less, 540 nm or less, or 535 nm or less.

The common layer COL1 may be arranged between the first electrode PE and the first light emitting layer ELa and/or the second light emitting layer ELb, and the common layer COL2 may be arranged above the first light emitting layer ELa and/or the second light emitting layer ELb. The common layers COL1 and COL2 may include a part arranged inside the pixel opening OP1 of the first pixel PXa and the second pixel PXb, and a part arranged outside the pixel opening OP1 and on top of the pixel insulating layer 150.

The common layers COL1 and COL2 may also include a portion arranged on the pixel insulating layer 150 arranged in the third pixel PXc. However, the common layers COL1 and COL2 may be removed and not be present within the pixel opening OP10 and the boundary opening OP3 of the third pixel PXc. The common layers COL1 and COL2 do not contact the first electrode PE of the third pixel PXc.

The common layers COL1 and COL2 may have a common layer opening OP13 that overlaps the boundary opening OP3 in a plan view. The side of the common layer opening OP13 may be connected to the side of the boundary opening OP3 and may be parallel (substantially parallel) to form one flat side.

The common layers COL1 and COL2 may have a common layer opening OP11 that overlaps the pixel opening OP10 of the third pixel PXc in a plan view. The side of the common layer opening OP11 may be connected to at least a portion of the side of the pixel opening OP10 and may be parallel (substantially parallel) to form one flat side. At least part of the side of the pixel opening OP10, which may be connected parallel to and may form a flat surface with the side of the common layer opening OP11, may form an acute angle with the third direction DR3 that is smaller than the acute angle formed by the side of the pixel opening OP1 with the third direction DR3. In such embodiments, at least a portion of the common layer opening OP11 of the common layers COL1 and COL2 and the pixel opening OP10 connected thereto may be formed through a laser cutting process to be described in more detail later.

The common layers COL1 and COL2 may be removed from at least a portion of the opening OP2 of the pixel insulating layer 150 and may not be present in the opening OP2. Referring to FIG. 4, the common layers COL1 and COL2 are removed from the opening OP2 and may have a common layer opening OP9 that overlaps the opening OP2 in a plan view. The common layer opening OP9 may be arranged within the opening OP2 of the pixel insulating layer 150, but the present disclosure is not limited thereto. The acute angle formed by the side surface of the common layer opening OP9 with the third direction DR3 may be smaller than the acute angle formed by at least a portion of the side surface of the opening OP2 with the third direction DR3. In such embodiments, the common layer opening OP9 of the common layers COL1 and COL2 may be formed through a laser cutting process to be described in more detail later. As shown in FIG. 4, according to one or more embodiments, the sides of the common layer openings OP9 including the common layers COL1 and COL2 may be connected to at least a part of the sides of the openings OP2 and aligned to form a single flat side. In such embodiments, at least a portion of the common layer opening OP9 of the common layers COL1 and COL2 and the opening OP2 of the pixel insulating layer 150 connected thereto may be formed through a laser cutting process to be described in more detail later.

The common layer COL1 may include a hole generation layer and/or a hole transport layer, and the common layer COL2 may include an electron generation layer and/or an electron transport layer.

Regarding the third pixel PXc, a plurality of third light emitting layers ELc and a plurality of common layers COL3, COL4, and COL5 may be arranged within the pixel opening OP10 of the pixel insulating layer 150.

The third light emitting layer ELc may include at least a portion of a low-molecular weight organic light emitting material, a high-molecular weight organic light emitting material such as poly 3,4-ethylenedioxythiophene (PEDOT), or an inorganic light emitting material. In the third pixel PXc, holes and electrons from the first electrode PE and the second electrode CE, are injected into the third light emitting layer ELc, and light of a third color which may be blue, may be emitted from the third light emitting layer ELc when excitons bound by the injected holes and electrons fall from the excited state to the ground state.

The common layer COL3 may be arranged between the first electrode PE and the third light emitting layer ELc, the common layer COL4 may be arranged between two adjacent third light emitting layers ELc, and the common layer COL5 may be arranged above the topmost third light emitting layer ELc. The common layers COL3, COL4, and COL5 may be mostly arranged within the pixel opening OP10.

A second electrode CE may be arranged on the common layers COL2 and COL5. The second electrode CE is also referred to as the common electrode and may include metals such as calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), or transparent conductive oxides such as ITO, IZO, IGZO, and/or ITZO. The second electrode CE may have a multilayer structure—for example, a double-layer structure such as magnesium (Mg)/silver (Ag). The second electrode CE may have translucent characteristics and, together with the first electrode PE, may form a microcavity through which light may reciprocate and resonate.

The second electrode CE may be connected throughout the plurality of first pixels PXa and the plurality of second pixels PXb in order to conduct electricity, and may be formed as one (common) electrode. The second electrode CE at the third pixel PXc may be physically and electrically separated from rest of the second electrode CE at the first pixel PXa and the second pixel PXb due to the step at the boundary opening OP3. The second electrode CE may include a portion CEp arranged within the boundary opening OP3, and the portion CEp of the second electrode CE arranged within the boundary opening OP3 may be separated from the rest of the part. The portion CEp of the second electrode CE arranged within the boundary opening OP3 is arranged on and may contact the blocking part SCE of the pixel electrode layer.

The first electrode PE, the first light emitting layer ELa, common layers COL1, COL2, and the second electrode CE of the first pixel PXa may together constitute the first light emitting element LEDa, which may be a light emitting diode. The first electrode PE, second light emitting layer ELb, common layers COL1, COL2, and second electrode CE of the second pixel PXb may together constitute a second light emitting element LEDb, which may be a light emitting diode. The first electrode PE of the third pixel PXc, a plurality of third light emitting layers ELc, the plurality of common layers COL3, COL4, COL5, and the second electrode CE may together constitute a third light emitting element LEDc, which may be a light emitting diode.

One of the first electrode PE and the second electrode CE may function as a cathode electrode and the other may function as an anode electrode. This description will focus on an example in which the first electrode PE may be an anode electrode and the second electrode CE may be a cathode electrode.

Within the area surrounded by the boundary opening OP3, the second electrode CE of the third pixel PXc may be electrically connected to the second voltage transfer electrode CVEE through the opening OP2 and/or the common layer opening OP9, allowing it to receive a common voltage. In one or more embodiments, outside the area surrounded by the boundary opening OP3, the second electrodes CE of the first pixel PXa and the second pixel PXb are connected to the second voltage transfer electrode CVEE and the first voltage transfer electrode CVE, or may be electrically connected to at least some of the other conductors connected thereto to receive a common voltage.

Referring to FIGS. 4 and 5, according to one or more embodiments, the third light emitting element LEDc may include a plurality of unit light emitting parts TLEU arranged between an anode, which may be the first electrode PE, and a cathode, which may be the second electrode CE. In one or more embodiments, the third pixel PXc of the display device may enhance the efficiency of the third light emitting element LEDc and improve the image display characteristics by including a plurality of unit light emitting parts TLEU for displaying an image.

Each unit light emitting part TLEU may include, a hole transport layer HTL, an auxiliary light emitting layer such as an electron transport layer ETL, and a third light emitting layer ELc. Charge generation layers N-CGL, P-CGL may be arranged between adjacent light emitting units TLEU. The charge generation layer N-CGL, P-CGL may include an n-type (kind) charge generation layer N-CGL and a p-type (kind) charge generation layer P-CGL. In the third pixel PXc, the n-type (kind) charge generation layer N-CGL and the p-type (kind) charge generation layer P-CGL may be in contact with each other to form an NP junction. Due to the NP junction, electrons and holes may be created concurrently (e.g., simultaneously) between the n-type (kind) charge generation layer N-CGL and the p-type (kind) charge generation layer P-CGL.

Referring to FIGS. 4 and 5, the common layer COL3 may include the hole transport layer HTL closest to the first electrode PE, the common layer COL4 may include the electron transport layer ETL, charge generation layers N-CGL, P-CGL, and hole transport layer HTL arranged between adjacent third emitting layers ELc, and the common layer COL5 may include the electron transport layer ETL closest to the second electrode CE.

FIG. 4 and FIG. 5 show an example in which the third light emitting element LEDc of the third pixel PXc includes two unit light emitting parts TLEU, but the present disclosure is not limited thereto, and each third light emitting element LEDc may include three or more light emitting units TLEU. For example, according to one or more embodiments, each third light emitting element may include three or more third light emitting layers ELc, and a plurality of common layers arranged between neighboring third light emitting layers ELc or between the anode or the cathode and the third light emitting layer ELc.

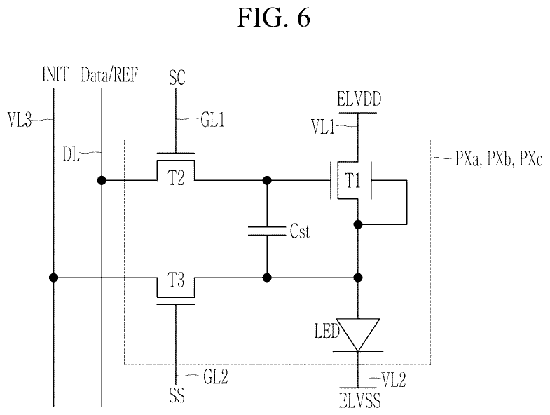

A pixel circuit of one pixel of a display device according to one or more embodiments will be described with reference to FIG. 6.

FIG. 6 is a pixel circuit diagram of one pixel of a display device according to one or more embodiments of the present disclosure.

Referring to FIG. 6, the pixel circuit of the pixels PXa, PXb, PXc included in the display device according to one or more embodiments may include first to third transistors T1-T3, a storage capacitor Cst, and a light emitting diode LED. The light emitting diode LED may be an organic or inorganic light emitting diode, and may be one of the first light emitting element LEDa, the second light emitting element LEDb, and/or the third light emitting element LEDc described above.

The gate electrode of the first transistor T1 may be connected to the first electrode of the storage capacitor Cst. The first electrode of the first transistor T1 may be connected to the driving voltage line VL1 that delivers the driving voltage ELVDD, and the second electrode of the first transistor T1 may be connected to the anode of the light emitting diode LED and the second electrode of the storage capacitor Cst.

The first transistor T1 may receive the data voltage Data according to the switching operation of the second transistor T2 and may supply a driving current to the light emitting diode LED according to the voltage stored in the storage capacitor Cst.

The gate electrode of the second transistor T2 may be connected to the first gate line GL1 that transmits the first scan signal SC. The first electrode of the second transistor T2 may be connected to a data line DL capable of transmitting the data voltage Data or the reference voltage REF. The second electrode of the second transistor T2 may be connected to the first electrode of the storage capacitor Cst and the gate electrode of the first transistor T1. The second transistor T2 may be turned on according to the first scan signal SC to transmit the reference voltage REF or the data voltage Data to the gate electrode of the first transistor T1.

The gate electrode of the third transistor T3 may be connected to the second gate line GL2 that transmits the second scan signal SS. The first electrode of the third transistor T3 may be connected to the initialization voltage line VL3 that transmits the initialization voltage INIT. The second electrode of the third transistor T3 may be connected to the second electrode of the storage capacitor Cst and the second electrode and anode of the first transistor T1. The third transistor T3 may be turned on according to the second scan signal SS and transmit the initialization voltage INIT to the anode to initialize the voltage of the anode.

The first electrode of the storage capacitor Cst may be connected to the gate electrode of the first transistor T1, and the second electrode of the storage capacitor Cst may be connected to the second electrode and anode of the third transistor T3. The cathode of the light emitting diode LED may be connected to the common voltage line VL2 that transmits the common voltage ELVSS.

The light emitting diode LED may be to emit light with a brightness (gradation) according to the driving current generated by the first transistor T1.

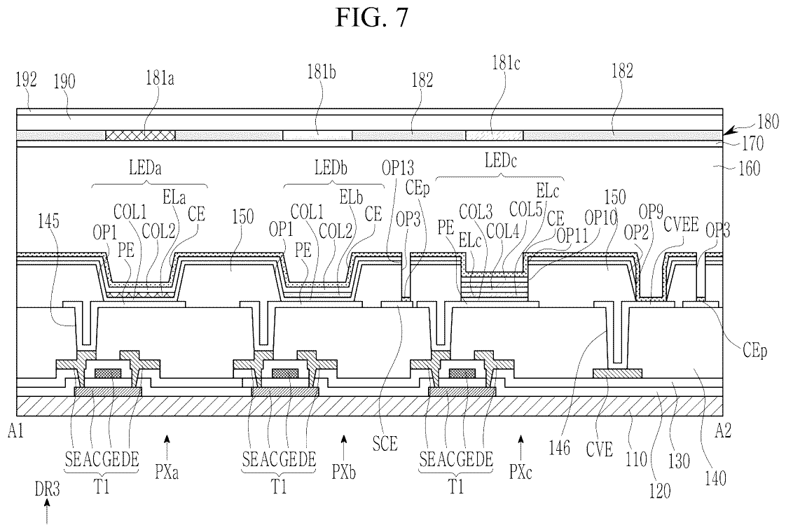

A display device according to one or more embodiments will be described with reference to FIG. 7 along with the previously described drawings.

FIG. 7 is a cross-sectional view of a display area of a display device according to one or more embodiments of the present disclosure.

Referring to FIG. 7, the display device according to this embodiment may be substantially identical to other display devices described in previous embodiments, but it may further include an encapsulation portion 160 arranged above the light emitting elements LEDa, LEDb, LEDc shown in FIG. 4. The encapsulation portion 160 may cover the light emitting elements LEDa, LEDb, LEDc and protect (substantially protect) them from external air or moisture. The encapsulation portion 160 may overlap the front surface of the display area DA in the direction in which the image is displayed, and may be partially arranged on the peripheral area PA. The encapsulation portion 160 may have a structure in which at least one inorganic layer and at least one organic layer are alternately stacked. Depending on the embodiment, the encapsulation portion 160 may be in the form of a substrate.

At least one insulating layer 170 may be arranged on the encapsulation portion 160.

A color filter layer 180 including a plurality of color filters 181a, 181b, 181c and a light blocking part 182 may be arranged on the insulating layer 170. The plurality of color filters 181a, 181b, 181c may include a first color filter 181a overlapping a light emitting region or the first light emitting layer Ela of a first pixel PXa, a second color filter 181b overlapping a light emitting region or a second light emitting layer ELb of a second pixel PXb and/or a third color filter 181c overlapping a light emitting region or third light emitting layer ELc of a third pixel PXc. The first color filter 181a may be to transmit light of the first color and absorb light of the remaining wavelengths, thereby increasing the purity of the light of the first color emitted to the outside of the display device. The second color filter 181b may be to transmit light of the second color and absorb light of the remaining wavelengths, thereby increasing the purity of the light of the second color emitted to the outside of the display device. The third color filter 181c may be to transmit light of the third color and absorb light of the remaining wavelengths, thereby increasing the purity of light of the third color emitted to the outside of the display device.

A light blocking part 182 capable of blocking light may be arranged between the color filters 181a, 181b, 181c. The light blocking part 182 may include a black pigment.

The color filter layer 180 may suppress or reduce external light reflection.

An overcoat layer 190 may be arranged on the color filter layer 180. The overcoat layer 190 may be arranged on the color filter layer 180 to protect (substantially protect) the color filter layer 180 and may flatten the upper surface of the color filter layer 180.

An outer film layer 192 may be arranged on the overcoat layer 190. Depending on the embodiment, the outer film layer 192 may include one of a polyethylene terephthalate (PET) film, a low-reflection film, a polarizing film, and/or a transmittance controllable film, but the present disclosure is not limited thereto. Depending on the embodiment, an upper substrate may be arranged instead of the outer film layer 192.

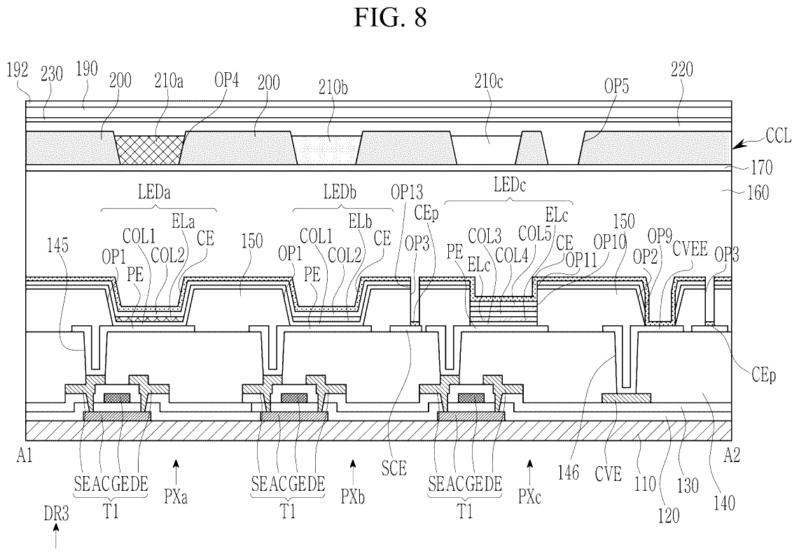

A display device according to one or more embodiments will be described with reference to FIG. 8 along with the previously described drawings.

FIG. 8 is a cross-sectional view of the display area of a display device according to one or more embodiments of the present disclosure.

Referring to FIG. 8, the display device according to this embodiment is substantially the same as the display device shown in FIG. 7 described above, but may include a color conversion layer CCL arranged on the encapsulation portion 160.

The color conversion layer CCL may include a first color conversion part 210a, a second color conversion part 210b, a transmission part 210c, and a bank 200.

The first color conversion part 210a may overlap the light emitting region or the first light emitting layer ELa of the first pixel PXa, the second color conversion part 210b may overlap the light emitting region or the second light emitting layer ELb of the second pixel PXb, and the transmission part 210c may overlap the light emitting region or the third light emitting layer ELc of the third pixel PXc.

The light emitted from the first pixel PXa may be to emit light of the first color with increased purity after passing through the first color conversion part 210a, and the light emitted from the second pixel PXb may be to emit light of the second color with increased purity after passing through the second color conversion part 210b. The third color light emitted from the third pixel PXc may be emitted by passing through the transmission part 210c.

The first color conversion part 210a and the second color conversion part 210b may include the quantum dots described above. The transmission part 210c may include a polymer resin and a scatterer included in the polymer resin, and may be to transmit light emitted from the third pixel PXc.

The bank 200 may be arranged between the emission areas of neighboring pixels PXa, PXb, PXc—that is, overlapping the non-light emitting regions. The bank 200 may have a bank opening OP4 that overlaps the light emitting region of each pixel PXa, PXb, PXc—that is, each light emitting layer ELa, ELb, ELc—in a plan view, and may have the first color conversion part 210a, the second color conversion part 210b, and the transmission part 210c, respectively, arranged within each bank opening OP4.

The bank 200 may include an organic material such as acrylic resin. The bank 200 may include a light absorbing material that absorbs the visible light wavelength band. According to one or more embodiments, the bank 200 may include organic light blocking material such as black pigments to serve as a light blocking member, and may act as a partition between the first color conversion part 210a, the second color conversion part 210b, and the transmission part 210c.

The bank 200 of the display device according to one or more embodiments may further include a bank hole OP5 that overlaps the non-light emitting region. The bank hole OP5 does not overlap the light emitting regions of (any of) the pixels PXa, PXb, PXc and may overlap the pixel insulating layer 150. When laminating the materials of the first color conversion part 210a, the second color conversion part 210b, and the transmission part 210c on the bank opening OP4 using an inkjet method, misprinting or overflow of ink may occur. Accordingly, it may be possible to prevent or reduce defects caused by the height of the bank 200 being increased, depending on the area, by providing the bank opening OP4 as an overflow area.

A filling layer 220 may be arranged on the color conversion layer CCL. The filling layer 220 may include an organic insulating material and/or an inorganic insulating material, and may have a flat top surface.

At least one insulating layer 230 may be arranged on the filling layer 220, and an overcoat layer 190 may be arranged on the insulating layer 230. The insulating layer 230 and the overcoat layer 190 may protect the color conversion layer CCL. Depending on the embodiment, the insulating layer 230 may not be provided.

An outer film layer 192 may be arranged on the overcoat layer 190. Depending on the embodiment, the outer film layer 192 may include one of a polyethylene terephthalate (PET) film, a low-reflection film, a polarizing film, and/or a transmittance controllable film, but the present disclosure is not limited thereto. Depending on the embodiment, an upper substrate may be arranged instead of the outer film layer 192.

Depending on the embodiment, the display device may include both the color filter layer 180 and the color conversion layer CCL shown in FIGS. 7 and 8. For example, a color conversion layer CCL as shown in FIG. 8 may be arranged on an encapsulation portion 160, and a color filter layer 180 as shown in FIG. 7 may be arranged on the color conversion layer CCL, or vice versa. The first color filter 181a of the color filter layer 180 may overlap the first color conversion part 210a of the color conversion layer CCL in the third direction DR3, allowing it to transmit the light of the first color that has passed through (e.g., been converted by) the first color conversion part 210a and absorb the light of other wavelengths. The second color filter 181b of the color filter layer 180 may overlap the second color conversion part 210b of the color conversion layer CCL in the third direction DR3, transmitting the second color light that has passed through (e.g., been converted by) the second color conversion part 210b and absorbing the light of other wavelengths. The third color filter 181c of the color filter layer 180 may overlap the transmission part 210c of the color conversion layer CCL in the third direction DR3, allowing the transmission of the third color light passing through the transmission part 210c and absorbing the light of other wavelengths. As a result, the purity of the color of light emitted by each pixel PXa, PXb, PXc may be further improved.

According to one or more embodiments, the pixels PXa, PXb, PXc may have different light emitting element structures depending on the wavelength of light emitted. The first and second light emitting layers ELa, ELb of the first and second pixels PXa, PXb, which emit light in the wavelength range of red and green, may include quantum dots to enhance the color purity, color reproduction, and/or the like, and the third light emitting layer ELc of the third pixel PXc, which emits light in the wavelength range of shorter blue light, may include a plurality of unit light emitting parts to improve the lifespan of the third light emitting element LEDc. In one or more embodiments, the first and second light emitting elements LEDa, LEDb of the first and second pixels PXa, PXb and the third light emitting element LEDc may be electrically separated to prevent or reduce leakage current between pixels, improving display quality.

According to one or more embodiments, the first electrode PE arranged at the first pixel PXa and the second pixel PXb may function as the cathode for the first and second light emitting elements LEDa, LEDb, and the second electrode CE may function as the anode. In such embodiments, the second electrode CE may be electrically connected to the lower first transistor T1 through a separate contact hole and may receive a data voltage.

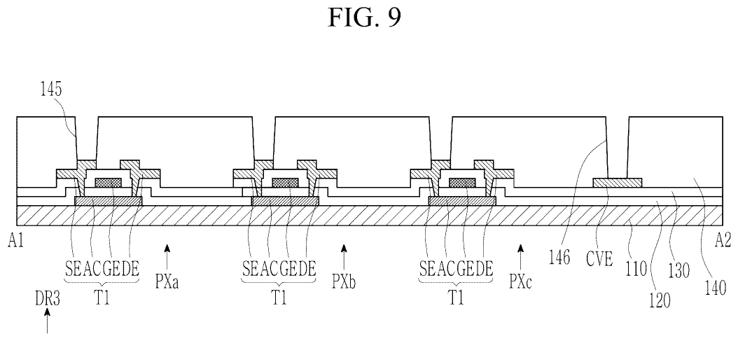

A method of manufacturing a display device according to one or more embodiments will be described with reference to FIGS. 9 to 16 along with the previously described drawings.

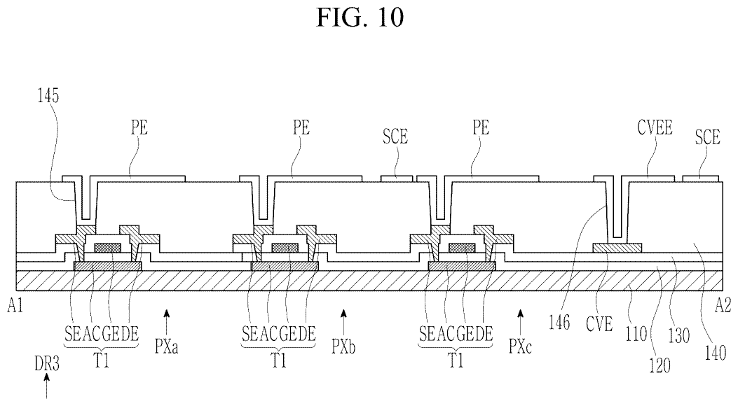

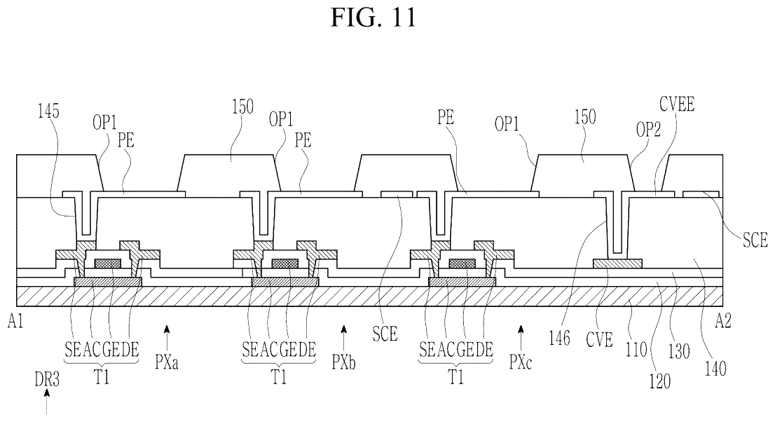

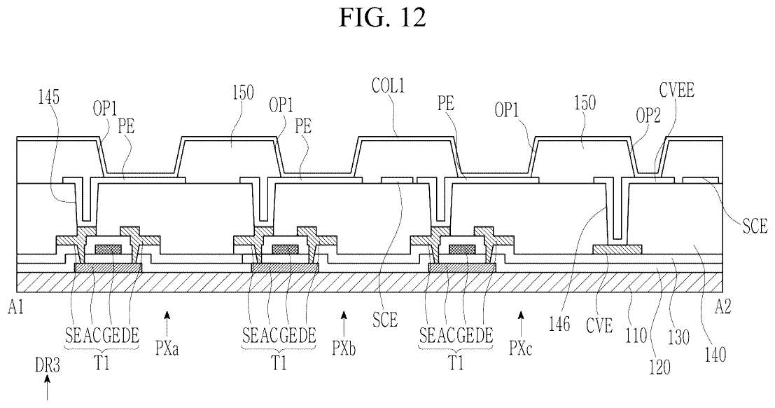

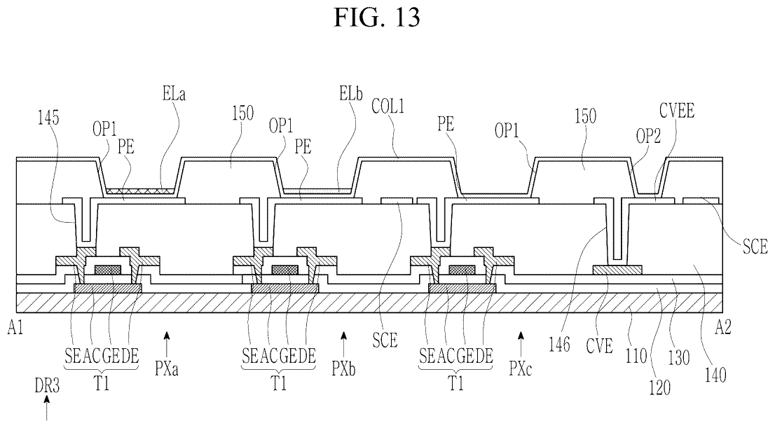

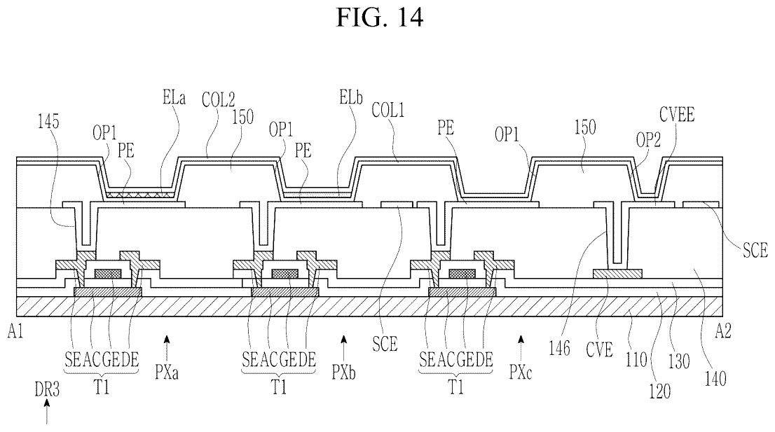

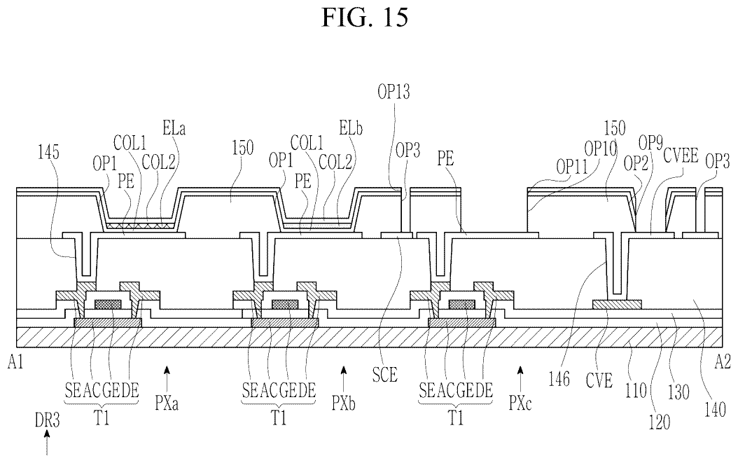

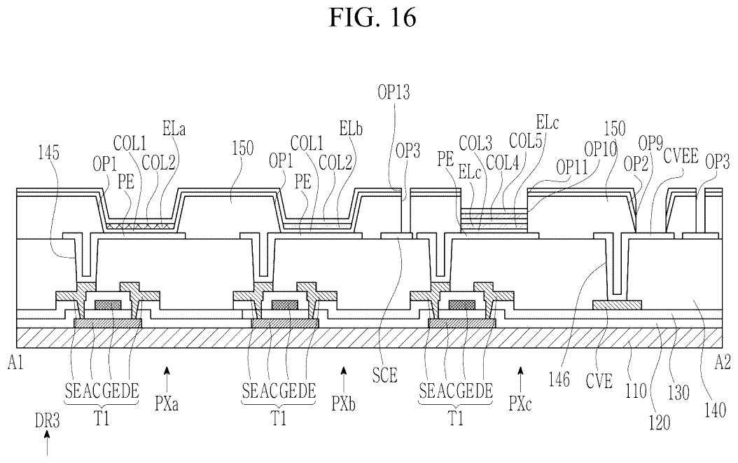

FIG. 9 is a cross-sectional view of the display device in a manufacturing process step (e.g., act or task) according to one or more embodiments of the present disclosure, FIG. 10 is a cross-sectional view of the display device in the next step (e.g., act or task) of the manufacturing process shown in FIG. 9, according to one or more embodiments of the present disclosure, FIG. 11 is a cross-sectional view of the display device in the next step (e.g., act or task) of the manufacturing process shown in FIG. 10, according to one or more embodiments of the present disclosure, FIG. 12 is a cross-sectional view of the display device in the next step (e.g., act or task) of the manufacturing process shown in FIG. 11, according to one or more embodiments of the present disclosure, FIG. 13 is a cross-sectional view of the display device in the next step (e.g., act or task) of the manufacturing process shown in FIG. 12, according to one or more embodiments of the present disclosure, FIG. 14 is a cross-sectional view of the display device in the next step (e.g., act or task) of the manufacturing process shown in FIG. 13, according to one or more embodiments of the present disclosure, FIG. 15 is a cross-sectional view of the display device in the next step (e.g., act or task) of the manufacturing process shown in FIG. 14, according to one or more embodiments of the present disclosure, and FIG. 16 is a cross-sectional view of the display device in the next step (e.g., act or task) of the manufacturing process shown in FIG. 15, according to one or more embodiments of the present disclosure.

Referring to FIG. 9, a semiconductor layer AC may be formed by stacking and patterning a semiconductor material on a substrate. Next, an insulating material may be stacked on the semiconductor layer AC and the substrate 110 to form the first insulating layer 120. Next, a conductive material may be stacked on the first insulating layer 120 and patterned to form the gate electrodes GE. Next, an insulating material may be stacked on the gate electrodes GE and the first insulating layer 120 to form the second insulating layer 130. Next, the first insulating layer 120 and the second insulating layer 130 may be patterned to form a plurality of contact holes arranged on the conductive regions of the semiconductor layer AC. Next, a conductive material may be stacked and patterned on the second insulating layer 130 to form a first conductive layer including the source electrodes SE, the drain electrodes DE, and the first voltage transfer electrodes CVE. Next, an insulating material may be stacked on the first conductive layer and the second insulating layer 130 to form the third insulating layer 140. Next, the third insulating layer 140 may be patterned to form the contact holes 145 arranged on the source electrodes SE and the contact holes 146 arranged on the first voltage transfer electrodes CVE. This may result in a plurality of pixel circuit parts of a plurality of pixels PXa, PXb, PXc on the substrate 110.

Next, referring to FIG. 10, a conductive material may be stacked and patterned on the third insulating layer 140 to form a pixel electrode layer including the first electrodes PE, the second voltage transfer electrodes CVEE, and the blocking sections SCE. Here, patterning may use, for example, a photo etching process or a photo process.

Referring to FIG. 11, an insulating material may be stacked on the pixel electrode layer and the third insulating layer 140 to form the pixel insulating layer 150, and the pixel insulating layer 150 may be patterned to form a plurality of pixel openings OP1 arranged above the first electrode PE of each pixel PXa, PXb, PXc, and the openings OP2 arranged above the second voltage transfer electrodes CVEE.

According to one or more embodiments, the pixel opening OP1 arranged in the third pixel PXc may not be formed.

Next, referring to FIG. 12, the common layer COL1 including a hole generation layer and/or a hole transport layer may be stacked on the pixel insulating layer 150 and the pixel electrode layer. This may be done by lamination or inkjet printing using an open mask with one opening for a plurality of pixels PXa, PXb, PXc in the deposition chamber.

Referring to FIG. 13, a luminescent material containing quantum dots may be stacked within the pixel openings OP1 on the first electrodes PE of some pixels—namely, the first pixel PXa and the second pixel PXb—to form the first luminescent layer ELa and the second luminescent layer ELb. In such embodiments, inkjet printing may be used.

Next, referring to FIG. 14, a common layer COL2 including an electron generation layer and/or an electron transport layer may be stacked on the common layer COL1, the first light emitting layer ELa, and the second light emitting layer ELb. This can be done by lamination or inkjet printing using an open mask with one opening for each of the plurality of pixels PXa, PXb, PXc in the deposition chamber.

Referring to FIG. 15, by patterning the common layers COL1, COL2 arranged at the third pixel PXc, the common layer opening OP11 arranged above the first electrode PE of the third pixel PXc, the common layer opening OP13 arranged above the blocking part SCE, and the common layer opening OP9 overlapping the opening OP2 of the pixel insulating layer 150 may be formed.

When forming the common layer opening OP11, the pixel insulating layer 150 below it may also be patterned to form the pixel opening OP10 of the third pixel PXc having a side parallel (substantially parallel) to and connected to the side of the common layer opening OP11. The pixel opening OP10 of the third pixel PXc may be formed larger than the previously formed pixel opening OP1, and the side of the pixel insulating layer 150 that defined the pixel opening OP1 may be removed.

When forming the common layer opening OP13, the pixel insulating layer 150 below it may also be patterned to form the boundary opening OP3 having a side surface parallel (substantially parallel) to and connected to the side surface of the common layer opening OP13.

When forming the common layer opening OP9, the pixel insulating layer 150 overlapping the common layer opening OP9 may not be patterned if the common layer opening OP9 is formed within the opening OP2 of the pixel insulating layer 150. Depending on the embodiment, when forming the common layer opening OP9, the pixel insulating layer 150 below the common layer opening OP9 may also be patterned. In such embodiments, the pixel insulating layer 150 may have an opening having a side surface parallel (substantially parallel) to and connected to the side surface of the common layer opening OP9.

In the manufacturing process shown in FIG. 15, laser-assisted cutting may be used if (e.g., when) forming the common layer openings OP11, OP13, OP9 and the pixel opening OP10 and boundary opening OP3 of the overlapping pixel insulating layer 150.

Next, referring to FIG. 16, the common layer COL3, the third light emitting layer ELc, the common layer COL4, the third light emitting layer ELc, and the common layer COL5 may be stacked in the pixel opening OP10 of the third pixel PXc. A deposition process or inkjet printing using a mask having an opening corresponding to the light emitting region of the third pixel PXc—that is, the pixel opening OP10—may be used. The mask used may be, for example, a fine metal mask. The common layers COL3, COL4, COL5 formed here may be separated from the previously formed common layers COL1, COL2.

Next, referring to FIG. 4, a conductive material may be stacked on the common layers COL2 and COL5 to form a second electrode CE. An open mask having one opening may be used for a plurality of pixels PXa, PXb, PXc in the deposition chamber. The portion CEp of the second electrode CE in the boundary opening OP3 may be formed on the blocking part SCE below the pixel insulating layer 150 and may contact the upper surface of the blocking part SCE. In the first pixel PXa and the second pixel PXb, the second electrode CE may be electrically and physically connected to each other, but in the third pixel PXc, the second electrode CE may be electrically and physically separated from the second electrode CE of other parts by the boundary opening OP3.

In an area adjacent to the third pixel PXc, the second electrode CE may be in contact with and electrically connected to the second voltage transfer electrode CVEE through the opening OP2 and/or the common layer opening OP9.

The display device according to the above embodiments can be applied to various electronic devices. An electronic device according to an embodiment comprises the aforementioned display device and may further comprise a module or a device with additional functions other than the display device.

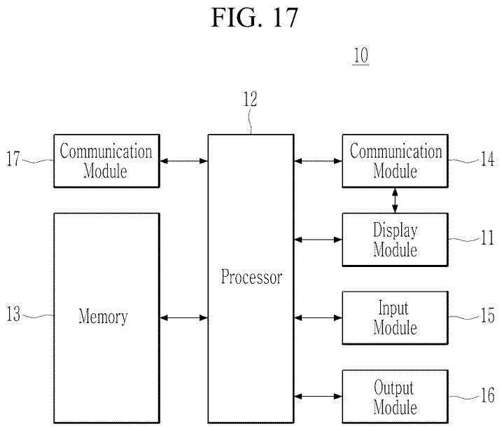

FIG. 17 is a block diagram of an electronic device according to an embodiment. Referring to FIG. 17, an electronic device 10 according to an embodiment may comprise a display module 11, a processor 12, a memory 13, and a power module 14. The electronic device 10 may further comprise an input module 15, a non-visual output module 16, and/or a communication module 17. The display module may comprise a display device according to an embodiment as described above.

The electronic device 10 may output various information in the form of images via the display module 11. When the processor 12 executes an application stored in the memory 13, an image information provided from the application may be provided to a user via the display module 11. The power module 14 may comprise a power supply module such as a power adapter or a battery device, and a power conversion module that converts the power supplied by the power supply module to generate the power necessary for operation of the electronic device 10. The input module 15 may provide an input information to the processor 12 and/or the display module 11. The non-visual output module 16 may receive information other than the image information, such as sound, haptic, or light information provided from the processor 12, and provide it to the user. The communication module 17 is responsible for transmitting and receiving information between the electronic device 10 and an external device, and may comprise a receiver and a transmitter.

At least one of the aforementioned components of the electronic device 11 may be included within the display device according to the above-described embodiments. In addition, some of the individual modules that are functionally included in one module may be included within the display device, while others may be provided separately from the display device. For example, a display device according to an embodiment may include the display module 11, while the processor 12, the memory 13, and the power module 14 may be provided in a form of other devices within the electronic device 11, not within the display device.

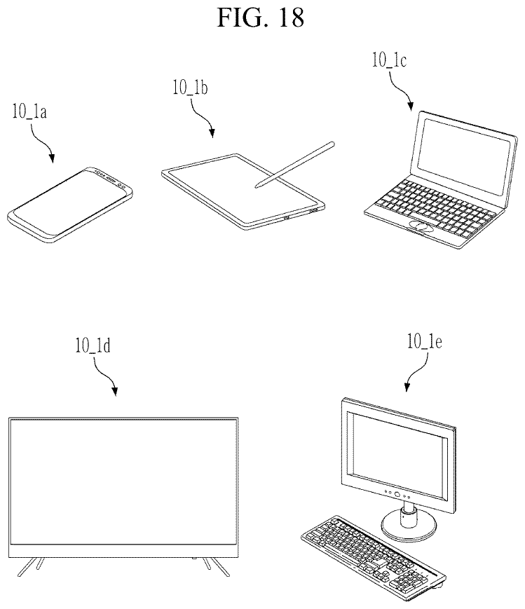

FIG. 18 to FIG. 20 are schematic diagrams of electronic devices according to various embodiments. FIG. 18 to FIG. 20 illustrate examples of various electronic devices to which a display device according to an embodiment is applied.

FIG. 18 illustrates examples of electronic devices, including a smartphone 10_1a, a tablet PC 10_1b, a laptop 10_1c, a TV 10_1d, and a desktop monitor 10_1e.

A smartphone 10_1a may comprise an input module such as a touch sensor and a communication module in addition to the display module 11. The smartphone 10_1a may process information received through the communication module or other input modules and display the information through the display module of the display device.

Each of the tablet PC 10_1b, the laptop 10_1c, the TV 10_1d, and the desktop monitor 10_1e may comprise a display module and an input module similar to the smartphone 10_1a, and may additionally comprise a communication module depending on embodiments.

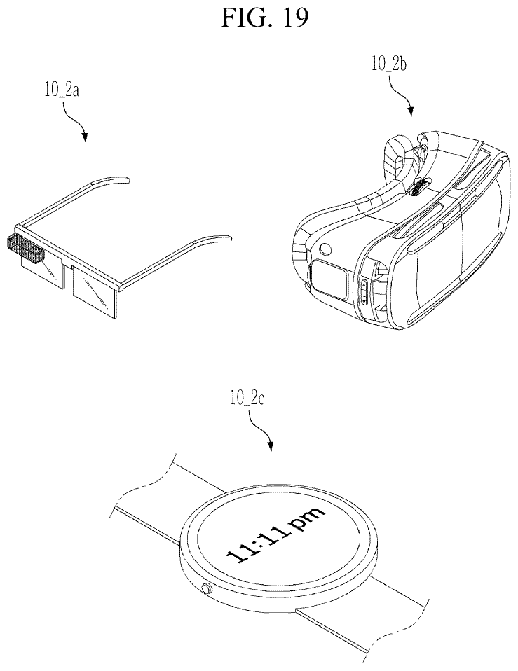

FIG. 19 illustrates an example where an electronic device including a display module is applied to a wearable electronic device. The wearable electronic device may be smart glasses 10_2a, a head-mounted display 10_2b, a smart watch 10_2c, and so on.

The smart glasses 10_2a and the head-mounted display 10_2b may comprise a display module that projects display images and a reflector that reflects the projected display images to provide it to a user's eyes, through which, a screen of virtual reality or augmented reality may be provided to the user.

The smart watch 10_2c may comprise a biometric sensor as an input device, and may provide biometric information recognized through the biometric sensor to a user via a display module.

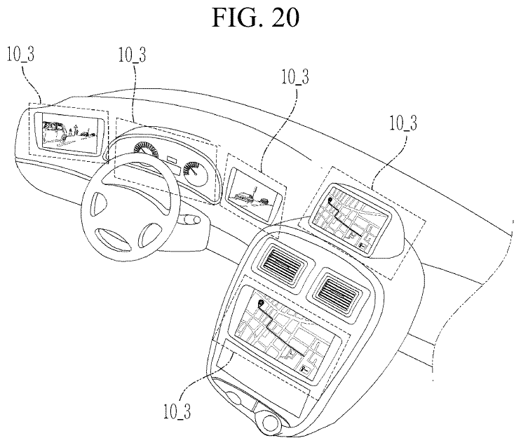

FIG. 20 illustrates an example of an electronic device including a display module applied to a vehicle. For example, an electronic device 10_3 may be applied to an instrument panel, or a center fascia, etc. of a car, or it may be applied to a CID (Center Information Display) placed on a dashboard of a car, or it may be applied to a room mirror display replacing a side mirror.

Although not illustrated, an electronic device to which a display device according to embodiments is applied may include not only devices primarily focused on screen display such as a billboard, an electronic signboard, and a gaming machine, but also various home appliances that display information through a display module, such as a refrigerator, a washing machine, a dryer, an air conditioner, and a robot vacuum cleaner. Furthermore, when the display module has a light-transmitting function, it can be applied to an electronic device such as a smart window or a transparent display device that show both the background and a displayed image. The types of electronic devices according to the embodiments are not limited to the examples given above, and application to various other electronic devices not mentioned may also be possible.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic apparatus, devices for manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

### REFERENCE NUMERALS

| | |
|---|---|
| 110: substrate | |
| 120, 130, 140, 170, 230: insulating layer | |
| 145, 146: contact hole | 50: pixel insulating layer |
| 180: color filter layer | 181a, 181b, 181c: color filter |
| 182: light blocking part | 190: overcoat layer |
| 192: outer film layer | 200: bank |
| 210a, 210b: color conversion part | 210c: transmission part |
| 220: filling layer | 1000: display device |
| AC: semiconductor layer | CE: second electrode |
| COL1, COL2, COL3, COL4, COL5: common layer | |
| CVE, CVEE: voltage transfer electrode | ELa, ELb, ELc: light emitting layer |
| LEDa, LEDb, LEDc: light emitting element | OP1, OP10: pixel opening |
| OP2: opening | OP3: boundary opening |
| OP4: bank opening | OP5: bank hole |
| OP9, OP11, OP13: common layer opening | PE: first electrode |
| PXLa, PXLb, PXLc: light emitting region | PXU: pixel group |
| PXa, PXb, PXc: pixel | SCE: blocking part |
| TLEU: unit light emitting part | |

What is claimed is:

1. A display device, comprising:
a substrate;
a plurality of pixels comprising a plurality of pixel circuit parts on the substrate;
a plurality of first electrodes on the plurality of pixel circuit parts;
a pixel insulating layer on the plurality of first electrodes;
a second electrode on the pixel insulating layer and the plurality of first electrodes;
a first pixel of the plurality of pixels comprising a first light emitting layer between a first electrode of the plurality of first electrodes and the second electrode; and
a second pixel of the plurality of pixels comprising a plurality of second light emitting layers between another first electrode of the plurality of first electrodes and the second electrode,
wherein the pixel insulating layer has a first pixel opening above the first electrode of the first pixel, and a second pixel opening above the other first electrode of the second pixel,
wherein the first pixel opening defines a light emitting region of the first pixel, and the second pixel opening defines a light emitting region of the second pixel, and
wherein the pixel insulating layer has a boundary opening between the light emitting region of the first pixel and the light emitting region of the second pixel.

2. The display device of claim 1, wherein, in a plan view, the boundary opening is in a closed curve shape around the light emitting region of the second pixel.

3. The display device of claim 2, wherein:
the pixel insulating layer further has a first opening between the light emitting region of the second pixel and the boundary opening, and
the first opening is within an area surrounded by the boundary opening.

4. The display device of claim 3, further comprising:
a first voltage transfer electrode on the substrate, and
a second voltage transfer electrode on the plurality of pixel circuit parts and electrically connected to the first voltage transfer electrode,
wherein the second electrode of the second pixel is electrically connected to the second voltage transfer electrode through the first opening.

5. The display device of claim 4, further comprising:
a first common layer on the first electrode of the first pixel and the pixel insulating layer,
wherein the first common layer has a first common layer opening that overlaps the first opening in the plan view.

6. The display device of claim 1, further comprising:
a first common layer on the first electrode of the first pixel and the pixel insulating layer,
wherein the first common layer has a second common layer opening that planarly overlaps the boundary opening.

7. The display device of claim 6, wherein a side surface of the second common layer opening is connected to a side surface of the boundary opening and is parallel to form a single flat side surface.

8. The display device of claim 1, further comprising:
a blocking part on the plurality of pixel circuit parts,
wherein the boundary opening is above the blocking part.

9. The display device of claim 8, wherein the second electrode at the second pixel is separated from the second electrode at the first pixel by a step of the boundary opening.

10. The display device of claim 9, wherein the second electrode is within the boundary opening and comprises a portion above the blocking part.

11. The display device of claim 1, further comprising:
a first common layer on the first electrode of the first pixel and the pixel insulating layer,
wherein the first common layer has a third common layer opening that overlaps the second pixel opening in a plan view.

12. The display device of claim 11, wherein a side surface of the third common layer opening is connected to a side surface of the second pixel opening and is parallel to form a flat side surface.

13. The display device of claim 12, wherein an acute angle defined by at least a portion of the side surface of the second pixel opening and a first direction perpendicular to a top surface of the substrate is smaller than an acute angle defined by the side surface of the first pixel opening and the first direction.

14. The display device of claim 1, wherein the first light emitting layer comprises quantum dots, and the plurality of second light emitting layers comprises an organic light emitting material.

15. The display device of claim 1, further comprising a plurality of second common layers alternately stacked with the plurality of second light emitting layers.

16. The display device of claim 1, wherein the first pixel is to emit red or green light, and the second pixel is to emit blue light.

17. The display device of claim 1, further comprising:
an encapsulation portion on the second electrode, and
at least one of a color filter layer or a color conversion layer on the encapsulation portion,
wherein the color conversion layer comprises quantum dots.

18. A method of manufacturing a display device, comprising:
forming a plurality of pixel circuit parts of a plurality of pixels on a substrate,
forming a plurality of first electrodes and a blocking part on the plurality of pixel circuit parts,
forming a pixel insulating layer on the plurality of first electrodes and the blocking part,
patterning the pixel insulating layer to form a first pixel opening of a first pixel of the plurality of pixels, the first pixel opening defining a light emitting region of the first pixel,
forming a first light emitting layer within the first pixel opening,
patterning the pixel insulating layer to form a boundary opening above the blocking part and a second pixel opening of a second pixel of the plurality of pixels, the second pixel opening defining a light emitting region of the second pixel,
forming a plurality of second light emitting layers within the second pixel opening, and
forming a second electrode on the first light emitting layer and the second light emitting layer,
wherein the boundary opening is between the light emitting region of the first pixel and the light emitting region of the second pixel.

19. The method of manufacturing the display device of claim 18, wherein:
the patterning of the pixel insulating layer to form the boundary opening and the second pixel opening comprises laser cutting the pixel insulating layer to form the boundary opening and the second pixel opening.

20. The method of manufacturing the display device of claim 19, further comprising:
forming a first common layer over a first electrode of the plurality of first electrodes and the pixel insulating layer at the first pixel prior to patterning the pixel insulating layer to form the boundary opening and the second pixel opening, and
forming a plurality of second common layers over another first electrode of the plurality of first electrodes at the second pixel after patterning the pixel insulating layer to form the boundary opening and the second pixel opening,
wherein in patterning the pixel insulating layer to form the boundary opening and the second pixel opening, the first common layer is patterned to form a common layer opening corresponding to each of the boundary opening and the second pixel opening.

21. An electronic device comprising:
a display device comprising
a substrate;
a plurality of pixels comprising a plurality of pixel circuit parts on the substrate;
a plurality of first electrodes on the plurality of pixel circuit parts;
a pixel insulating layer on the plurality of first electrodes;
a second electrode on the pixel insulating layer and the plurality of first electrodes;
a first pixel of the plurality of pixels comprising a first light emitting layer between a first electrode of the plurality of first electrodes and the second electrode; and
a second pixel of the plurality of pixels comprising a plurality of second light emitting layers between another first electrode of the plurality of first electrodes and the second electrode,
wherein the pixel insulating layer has a first pixel opening above the first electrode of the first pixel, and a second pixel opening above the another first electrode of the second pixel,
wherein the first pixel opening defines a light emitting region of the first pixel, and the second pixel opening defines a light emitting region of the second pixel, and
wherein the pixel insulating layer has a boundary opening between the light emitting region of the first pixel and the light emitting region of the second pixel.

22. The electronic device of claim 21, wherein the electronic device comprises a mobile phone, a smartphone, a tablet personal computer, a mobile communication terminal, an electronic notebook, an e-book, a portable multimedia player, a navigation system, an ultramobile personal computer, a television, a laptop, a monitor, a billboard, a smart watch, a watch phone, a glasses-type display, a head mounted display, or a car display.
